(19) United States
(12) Patent Application Publication
(10) Pub. No.: US 2026/0165216 A1
(43) Pub. Date: Jun. 11, 2026

(54) PACKAGE STRUCTURE AND METHOD FOR FORMING THE SAME, SEMICONDUCTOR STRUCTURE

(71) Applicant: JCET Group Co., Ltd., Jiangyin (CN)

(72) Inventors: Danfeng YANG, Jiangyin (CN); Songhua XU, Jiangyin (CN); Shasha ZHOU, Jiangyin (CN); Yao LI, Jiangyin (CN); Yaojian LIN, Jiangyin (CN)

(73) Assignee: JCET Group Co., Ltd., Jiangyin (CN)

(21) Appl. No.: 19/179,051

(22) Filed: Apr. 15, 2025

(30) Foreign Application Priority Data
Apr. 16, 2024 (CN) 202410454623.X

(51) Int. Cl. H10W 90/00; H10W 70/05; H10W 70/63; H10W 74/10

(52) U.S. Cl. CPC H10W 90/401; H10W 70/096; H10W 70/635; H10W 74/111

(57) ABSTRACT

The present disclosure relates to a package structure, a method for forming the same, and a semiconductor structure. The package structure comprises: a first substrate; a second substrate, located above the first substrate; a package body, located between the first substrate and the second substrate, the package body comprising a semiconductor chip, a functional device, and a plurality of first interconnection structures located on at least one side of the semiconductor chip, the first interconnection structures electrically connecting the first substrate to the second substrate, the plurality of the first interconnection structures located on the same side of the semiconductor chip are arranged at intervals, and the functional device is located within an interval area between the adjacent first interconnection structures.

### CROSS-REFERENCE TO RELATED APPLICATIONS

This application claims the benefit of priority to Chinese Application No. 202410454623.X, filed on Apr. 16, 2024, which is hereby incorporated by reference in its entirety.

### TECHNICAL FIELD

The present disclosure relates to the technical field of integrated circuit manufacturing, and particularly relates to a package structure and a method for forming the same, and a semiconductor structure.

### BACKGROUND

Embedded 3D Interconnect (eBar) is used to realize vertical electrical connection between the top substrate and the bottom substrate inside a package body, and has a wide range of applications in System In a Package (SiP) with high density. However, the embedded three-dimensional vertical interconnection components inside the package structure are usually regularly distributed on the sides of the package body with the same spacing distance, which limits the flexibility of the package body design and is not conducive to the improvement and development of the performance of the package structure. Moreover, in the manufacturing process of the package structure, the way of regularly distributing the embedded three-dimensional vertical interconnection components on the sides of the package body is very likely to lead to deformation, such as warping of the package structure, especially when the embedded three-dimensional vertical interconnection components cross a dicing lane area, the warping deformation is more serious. In addition, the way in which the embedded three-dimensional vertical interconnection components are regularly distributed on the sides of the package body occupies a larger space inside the package structure, thereby limiting the further improvement of the integration degree of the package structure.

### SUMMARY

According to some embodiments, the present disclosure provides a package structure, comprising: a first substrate; a second substrate, located above the first substrate; a package body, located between the first substrate and the second substrate, the package body comprising a semiconductor chip, a functional device, and a plurality of first interconnection structures located on at least one side of the semiconductor chip, the first interconnection structures electrically connecting the first substrate to the second substrate, the plurality of the first interconnection structures located on the same side of the semiconductor chip are arranged at intervals, and the functional device is located within an interval area between the adjacent first interconnection structures.

In some embodiments, two first interconnection structures are arranged at intervals on the same side of the semiconductor chip, and the two first interconnection structures are symmetrically distributed with respect to the functional device.

In some embodiments, the plurality of the first interconnection structures are distributed in a first direction on opposite sides of the semiconductor chip.

In some embodiments, for the first interconnection structures distributed in the first direction on opposite sides of the semiconductor chip, the spacing distance between the adjacent first interconnection structures located on one side of the semiconductor chip is the same as or different from the spacing distance between the adjacent first interconnection structures located on the other side of the semiconductor chip.

In some embodiments, the package body further comprises a molding layer filled between the first substrate and the second substrate.

In some embodiments, the molding layer molds the semiconductor chip, the functional device, and the first interconnection structure, and the molding layer fully fills the interval area between the adjacent first interconnection structures.

In some embodiments, the first interconnection structure further comprises a plurality of first bottom pins electrically connected to the first substrate, and there is a first spacing distance between the adjacent first bottom pins.

In some embodiments, in the plurality of the first interconnection structures, there is at least one of the first interconnection structures in which the first spacing distance is different from the first spacing distance in another first interconnection structure.

In some embodiments, the semiconductor chip is located in the middle of the package body, and the first interconnection structure is located at the edge of the package body; the package body further comprises: a second interconnection structure, located in the middle of the package body, the second interconnection structure electrically connecting the first substrate to the second substrate, the second interconnection structure comprising a plurality of second bottom pins electrically connecting the first substrate, and there is a second spacing distance between the adjacent second bottom pins, the second spacing distance being less than the first spacing distance.

According to yet other embodiments, the present disclosure also provides a semiconductor structure, comprising: a first base substrate, the first base substrate comprising a plurality of first redistribution layers; a second base substrate, located on a top surface of the first base substrate in a second direction, and the second base substrate comprises a plurality of second redistribution layers, the first direction being parallel to the top surface of the first base substrate and the second direction being perpendicular to the top surface of the first base substrate; a plurality of package bodies, located between the first base substrate and the second base substrate, each of the package bodies comprising a semiconductor chip, a functional device, and a plurality of first interconnection structures located on at least one side of the semiconductor chip, the first interconnection structures electrically connecting the first base substrate to the second base substrate, the plurality of the first interconnection structures located on the same side of the semiconductor chip are arranged at intervals, and the functional device located within an interval area between the adjacent the first interconnection structures.

In some embodiments, it further comprises: a dicing lane area, extending from the second base substrate to the first base substrate in the second direction; a connection structure, located between the adjacent package bodies in the first direction, and the dicing lane area passing through the connection structure in the second direction, the connection structure connecting the first interconnection structures in the two adjacent package bodies.

In some embodiments, the connection structure comprises: an isolation layer, the isolation layer connecting the first interconnection structures in the two adjacent package bodies; grooves, located within the isolation layer, and the grooves are located within the dicing lane area. In some embodiments, the plurality of the first interconnection structures located on the same side of the semiconductor chip within the package are arranged at intervals in a third direction, the third direction being parallel to the top surface of the first base substrate and the first direction intersecting with the third direction.

In some embodiments, the grooves comprise: a first groove, located between the first interconnection structures in the two adjacent package bodies; and a second groove, located on the outside of the first groove in a third direction, and the length of the first groove in the third direction is greater than the length of the second groove in the third direction.

In some embodiments, it further comprises: a molding compound, filled between the first base substrate and the second base substrate and molding the semiconductor chip, the functional device, and the first interconnection structure, and the molding compound fully fills the groove.

According to yet further embodiments, the present disclosure also provides a method for forming a package structure, comprising the following steps: forming a first substrate, a second substrate, and a package body located between the first substrate and the second substrate, the package body comprising a semiconductor chip, a functional device, and a plurality of first interconnection structures located on at least one side of the semiconductor chip, the first interconnection structures electrically connecting the first base substrate to the second base substrate, the plurality of the first interconnection structures located on the same side of the semiconductor chip are arranged at intervals, the functional device is located within an interval area between the adjacent first interconnection structures.

In some embodiments, the specific steps for forming a first substrate, a second substrate, and a package body located between the first substrate and the second substrate comprise: forming a first base substrate, the first base substrate comprising a plurality of first redistribution layers; forming a plurality of the package bodies corresponding one-to-one to a plurality of the first redistribution layers on a top surface of the first base substrate in a second direction, and the plurality of the first redistribution layers being electrically connected one-to-one to the first interconnection structure in a plurality of the package bodies, the first direction being parallel to the top surface of the first base substrate and the second direction being perpendicular to the top surface of the first base substrate; forming a second base substrate on the plurality of the package bodies in the second direction, the second base substrate comprising a plurality of second redistribution layers corresponding one-to-one to the plurality of package bodies, and the plurality of the second redistribution layers being electrically connected one-to-one to the first interconnection structure in the plurality of the package bodies; consecutively dicing the first base substrate and the second base substrate in the second direction, dividing the first base substrate into a plurality of the first substrates, dividing the second base substrate into a plurality of the second substrates and separating a plurality of the package bodies to form a plurality of the package structures independent of each other.

In some embodiments, the specific steps for forming a plurality of the package bodies corresponding one-to-one to a plurality of the first redistribution layers on a top surface of the first base substrate in a second direction comprise: defining in the first base substrate a mounting area and a first dicing lane area located between adjacent mounting areas, the first redistribution layer being located within the mounting area; mounting the semiconductor chip, the functional device and the first interconnection structure on the mounting area and connecting the first interconnection structures on the adjacent mounting areas through a connection structure located on the first dicing lane area.

In some embodiments, the specific steps of prior to mounting the semiconductor chip, the functional device, and the first interconnection structure on the mounting area, and connecting the first interconnection structures on the adjacent mounting areas through a connection structure located on the first dicing lane area comprise: forming an initial connection structure comprising the plurality of the first interconnection structures and located between the adjacent first interconnection structures and connecting connection structures of the plurality of the first interconnection structures; mounting the semiconductor chip and the functional device in the mounting area and mounting the initial connection structure on the first base substrate such that the first interconnection structure of the initial connection structure is located within the mounting area and the connection structure is located within the first dicing lane area.

In some embodiments, the steps of mounting the semiconductor chip, the functional device and the first interconnection structure on the mounting area comprise: mounting the semiconductor chip and the second interconnection structure in the middle of the mounting area, mounting the first interconnection structure and the functional device at the edge of the mounting area, the second interconnection structure being electrically connected to the first redistribution layer.

In some embodiments, the connection structure comprises an isolation layer connecting the adjacent first interconnection structures and a groove located within the isolation layer; and prior to consecutively dicing the first base substrate and the second base substrate in the second direction, further comprising the following steps: filling between the first base substrate and the second base substrate with a molding compound which molds the semiconductor chip, the functional device, and the first interconnection structure, and the molding compound fully fills the groove.

In some embodiments, the second base substrate comprises a second dicing lane area corresponding to the first dicing lane area; the specific steps of consecutively dicing the first base substrate and the second base substrate in the second direction comprise: consecutively dicing the second dicing lane area, the initial connection structure and the first dicing lane area in the second direction, dividing the first base substrate into a plurality of the first substrates, dividing the second base substrate into a plurality of the second substrates and dividing the initial connection structure into a plurality of independent first interconnection structures.

### BRIEF DESCRIPTION OF THE DRAWINGS

FIG. 1 is a first schematic top view of the package structure in some embodiments of the present disclosure;

FIG. 2 is a second schematic top view of the package structure in some embodiments of the present disclosure;

FIG. 3 is a third schematic top view of the package structure in some embodiments of the present disclosure;

FIG. 4 is a schematic sectional view of the package structure in some embodiments of the present disclosure;

FIG. 5 is a first schematic top view of a semiconductor structure in some embodiments of the present disclosure;

FIG. 6 is a second schematic top view of a semiconductor structure in some embodiments of the present disclosure;

FIG. 7 is a third schematic top view of a semiconductor structure in some embodiments of the present disclosure;

FIG. 8 is a fourth schematic top view of a semiconductor structure in some embodiments of the present disclosure;

FIG. 9 is a schematic sectional view of a semiconductor structure in some embodiments of the present disclosure;

FIG. 10 is a flowchart of a method for forming a package structure in some embodiments of the present disclosure; and

FIGS. 11-14 are schematic diagrams of the main process structures of the process for forming the package structure in some embodiments of the present disclosure.

### DETAILED DESCRIPTION

Specific embodiments of the package structure and the method for forming the same and the semiconductor structure provided by the present disclosure are described in detail below in conjunction with the accompanying drawings.

An urgent technical problem that needs to be solved at present is how to improve the integration degree of the package structure and reduce the probability of deformation, such as warping of the package structure during the manufacturing process, so as to realize the improvement of the performance of the package structure.

The present disclosure provides a package structure and a method for forming the same, and a semiconductor structure, for improving the integration degree of the package structure and reducing the probability of deformation, such as warping of the package structure during the manufacturing process, so as to realize the improvement of the performance of the package structure and the improvement of the manufacturing yield of the package body.

In the package structure and the method for forming the same, as well as the semiconductor structure provided by the present disclosure, by providing a plurality of first interconnection structures on at least one side of a semiconductor chip within a package body, and arranging a plurality of the first interconnection structures located on the same side of the semiconductor chip at intervals, the deformation such as warping of the package structure during manufacturing caused by too long length of the first interconnection structures is avoided, and the manufacturing yield of the package structure is improved and the performance of the package structure is ensured. By providing functional devices in the interval area between the adjacent first interconnection structures on one side of the semiconductor chip, the utilization rate of space in the package is improved, thereby enabling more components to be integrated within the package, and the integration degree of the package structure is improved, which helps to realize high-density package integration and extend the functions of the package structure.

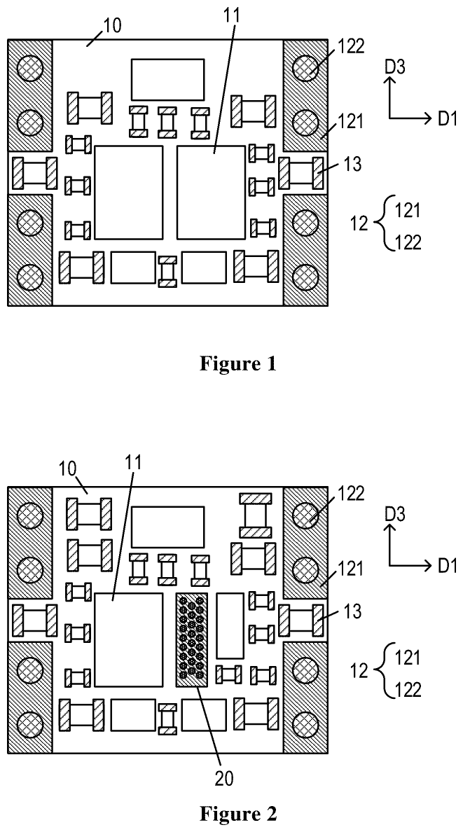

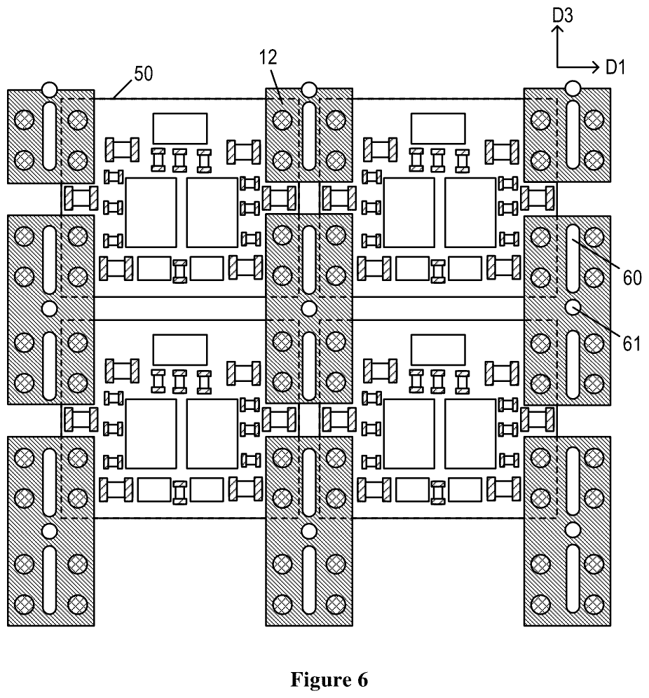

The present specific embodiment provides a package structure. FIG. 1 is a first schematic top view of the package structure in some embodiments of the present disclosure, and FIG. 4 is a schematic sectional view of the package structure in some embodiments of the present disclosure. As shown in FIGS. 1 and 4, the package structure comprises: a first substrate 10; a second substrate 40, located above the first substrate 10; a package body 41, located between the first substrate 10 and the second substrate 40, the package body 41 comprising a semiconductor chip 11, a functional device 13, and a plurality of first interconnection structures 12 located on at least one side of the semiconductor chip 11, the first interconnection structures 12 electrically connecting the first substrate 10 to the second substrate 40, the plurality of the first interconnection structures 12 located on the same side of the semiconductor chip 11 are arranged at intervals and the functional device 13 is located within an interval area between adjacent the first interconnection structures 12.

By way of example, the first substrate 10 has a first redistribution layer within it, the second substrate 40 has a second redistribution layer within it, the second substrate 40 is located on the top surface of the first substrate 10 in a second direction D2, and the second direction D2 is perpendicular to the top surface of the first substrate 10. The package body 41 is located between the first substrate 10 and the second substrate 40 in the second direction D2. The package body 41 comprises the semiconductor chip 11, the functional device 13, and the first interconnection structure 12, all mounted on the top surface of the first substrate 10. The semiconductor chip 11 is electrically connected to the first substrate 10, the functional device 13 is electrically connected to the first substrate 10, and the first interconnection structure 12 is electrically connected to the first substrate 10 at one end and electrically connected to the second substrate 40 at the other end. In one example, the functional device 13 may be a discrete device or a passive device. The first interconnection structure 12 is distributed on the outside of the semiconductor chip 11 in a direction (e.g., the first direction D1) parallel to the top surface of the first substrate 10. In order to clearly illustrate the package structure, the second substrate 40 is not shown in FIG. 1.

In the present specific embodiment, a plurality of the first interconnection structures 12 located on the same side of the semiconductor chip 11 in a direction parallel to the top surface of the first substrate 10 (e.g., first direction D1) are arranged at intervals in a direction parallel to the top surface of the first substrate 10 (e.g., third direction D3), so as to avoid the problem of the stresses exerted on the first substrate 10 being excessive due to the too long length of the first interconnection structures, and reducing the probability of deformation such as warping of the package structure during the manufacturing process, and improving the performance and manufacturing yield of the package structure. A plurality of the first interconnection structures 12 located on the same side of the semiconductor chip 11 are arranged at intervals in a direction (e.g., the third direction D3) parallel to the top surface of the first substrate 10, so that the functional devices 13 can be provided in the interval area between adjacent the first interconnection structures 12, such that the utilization of space in the package body 41 is improved, and more components can be integrated into the package, and the integration degree of the package structure is improved, and it helps to realize high-density package integration and extend the functions of the package structure. The first direction D1 intersects (e.g., intersects at an incline or perpendicularly) with the third direction D3.

In order to further simplify the manufacturing process of the package structure, in some embodiments, two first interconnection structures 12 are arranged at intervals on the same side of the semiconductor chip 11, and two first interconnection structures 12 are symmetrically distributed with respect to the functional device 13.

By way of example, as shown in FIG. 1, on the side of the semiconductor chip 11 in the first direction D1, two first interconnection structures 12 are arranged at intervals in the third direction D3, and one of the functional devices 13 is located between two the first interconnection structures 12, and the first interconnection structures 12 are symmetrically distributed with respect to the functional device 13, thereby improving the uniformity of the external pattern arrangement of the semiconductor chip 11, and simplifying the manufacturing process of the package structure.

In some embodiments, a plurality of the first interconnection structures 12 are distributed in the first direction D1 on opposite sides of the semiconductor chip 11.

For the first interconnection structures 12 distributed in the first direction D1 on opposite sides of the semiconductor chip 11, the spacing distance between adjacent first interconnection structures 12 located on one side of the semiconductor chip 11 is the same as or different from the spacing distance between adjacent first interconnection structures 12 located on the other side of the semiconductor chip 11.

In one example, the spacing distance between adjacent first interconnection structure 12 located on one side of the semiconductor chip 11 is the same as the spacing distance between adjacent first interconnection structures 12 located on the other side of the semiconductor chip 11, thereby further simplifying the manufacturing process of the package structure. In another example, the spacing distance between adjacent first interconnection structures 12 located on one side of the semiconductor chip 11 is different from the spacing distance between adjacent first interconnection structures 12 located on the other side of the semiconductor chip 11, so that the spacing distance between adjacent first interconnection structures 12 can be adjusted according to the need, which not only improves the flexibility of the manufacturing of the package structure but also meets the requirements of mounting different functional devices 13, further extending the application field of the package structure.

In order to further improve the stability of the performance of the package structure, in some embodiments, the package body 41 further comprises a molding layer 46 filled between the first substrate 10 and the second substrate 40.

The molding layer 46 molds the semiconductor chip 11, the functional device 13, and the first interconnection structure 12, and the molding layer 46 fully fills the interval area between adjacent first interconnection structures 12. In one example, the material of the molding layer 46 may be an epoxy resin molding compound.

In some embodiments, the first interconnection structure 12 further comprises a plurality of first bottom pins 45 electrically connected to the first substrate 10, with a first spacing distance between adjacent the first bottom pins 45.

In the plurality of the first interconnection structures 12, there exists at least one of the first spacing distances in the first interconnection structure 12 that is different from the first spacing distance in another first interconnection structure 12.

Specifically, the first interconnection structure 12 comprises a first dielectric layer 42, a first cover layer 121 covering the surface of the first dielectric layer 42, a first conductive pillar 43 running in the second direction through the first dielectric layer 42, a first top pin 122 located above the first conductive pillar 43, and a first bottom pin 45 located below the first conductive pillar 43, wherein the first top pin 122 electrically connects the second substrate 40 to the first conductive pillar 43, the first bottom pin 45 electrically connects the first substrate 10 to the first conductive pillar 43. Each of the first interconnection structures 12 may comprise a plurality of the first top pins 122 arranged at intervals in a direction (e.g., in the first direction D1) parallel to a top surface of the first substrate 10, and a plurality of the first bottom pins 45 arranged at intervals in a direction (e.g., in the first direction D1) parallel to a top surface of the first substrate 10. At least two of the first interconnection structures 12 are present in the package structure (two of the first interconnection structures 12 may be located on the same side of the semiconductor chip 11 in the first direction D1 or on opposite sides of the semiconductor chip 11 in the first direction D1), wherein the first spacing distance between adjacent first bottom pins 45 within one of the first interconnection structures 12 is not equal to the first spacing distance between adjacent first bottom pins 45 within the other one of the first interconnection structures 12, in order to further increase the flexibility of the design and manufacture of the package structure. In one example, the material of the first cover layer 121 may be an insulation material.

In some embodiments, there are at least two the first interconnection structures 12 in the package structure (the two first interconnection structures 12 may be located on the same side of the semiconductor chip 11 in the first direction D1 or on opposite sides of the semiconductor chip 11 in the first direction D1), wherein the spacing distance between adjacent first top pins 122 within one of the first interconnection structure 12 is unequal to the spacing distance between adjacent first top pins 122 within the other one of the first interconnection structures 12, in order to flexibly adjust the specific configuration of the first interconnection structure according to functional requirements.

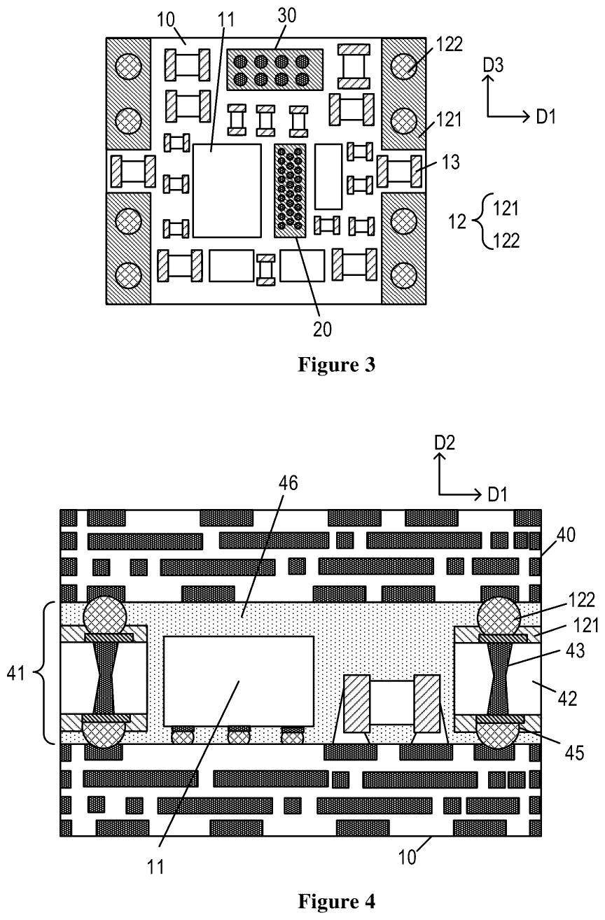

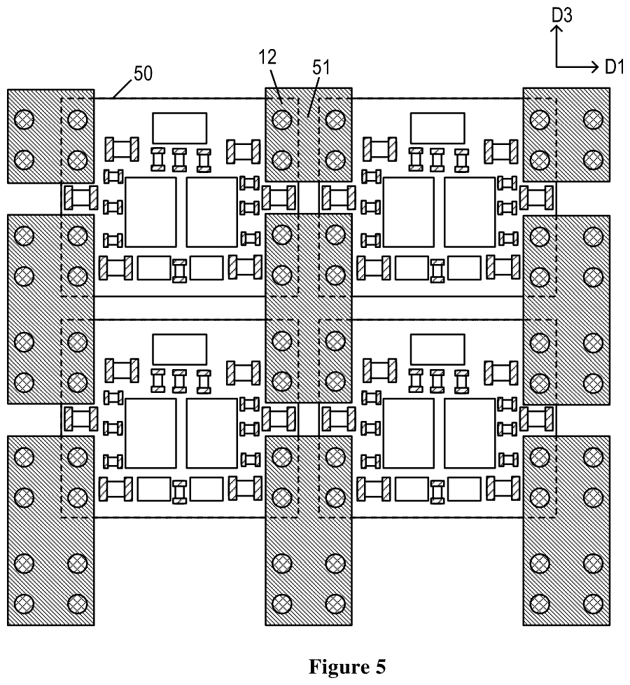

FIG. 2 is a second schematic top view of the package structure in some embodiments of the present disclosure, and FIG. 3 is a third schematic top view of the package structure in some embodiments of the present disclosure. In some embodiments, as shown in FIGS. 2 and 3, the semiconductor chip 11 is located in the middle of the package body 41, and the first interconnection structure 12 is located at the edge of the package body 41.

The package body 41 further comprises a second interconnection structure 20, located in the middle of the package body 41, the second interconnection structure 20 electrically connecting the first substrate 10 to the second substrate 40, the second interconnection structure 20 comprising a plurality of second bottom pins electrically connecting the first substrate 10, adjacent second bottom pins having a second spacing distance between them, the second spacing distance being less than the first spacing distance.

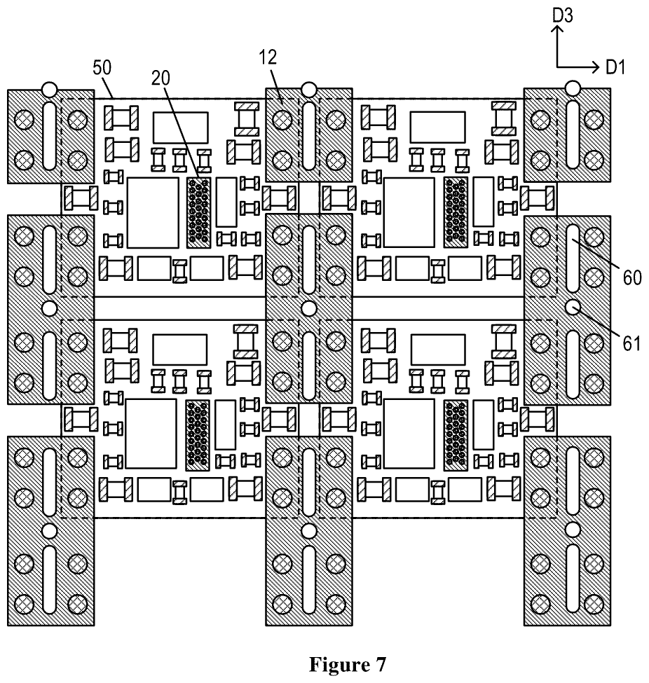

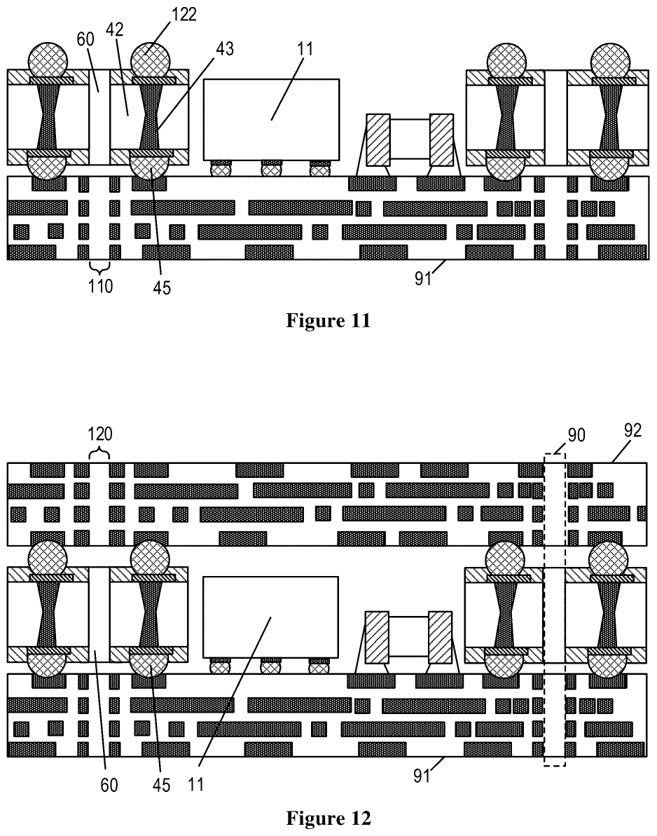

The present specific embodiment also provides a semiconductor structure. FIG. 5 is a first schematic top view of a semiconductor structure in some embodiments of the present disclosure, FIG. 9 is a schematic sectional view of a semiconductor structure in some embodiments of the present disclosure, and the structure of the package body described in the present specific embodiment can be seen in FIGS. 1-4.

As shown in FIGS. 1-5 and FIG. 9, the semiconductor structure comprises: a first base substrate 91, the first base substrate 91 comprising a plurality of first redistribution layers; a second base substrate 92, located on a top surface of the first base substrate 91 in a second direction D2, and the second base substrate 92 comprising a plurality of second redistribution layers, the first direction D1 being parallel to the top surface of the first base substrate 91 and the second direction D2 being perpendicular to the top surface of the first base substrate 91; a plurality of package bodies 41, located between the first base substrate 91 and the second base substrate 92, each of the package bodies 41 comprising a semiconductor chip 11, a functional device 13, and a plurality of first interconnection structures 12 located on at least one side of the semiconductor chip 11, the first interconnection structures 12 electrically connecting the first base substrate 91 to the second base substrate 92, the plurality of the first interconnection structures 12 located on the same side of the semiconductor chip 11 are arranged at intervals, the functional device 13 is located within an interval area between adjacent first interconnection structures 12.

The semiconductor structure comprises a set of the first base substrate and the second base substrate corresponding to each other, and one of the package bodies 41 located between the set of the first base substrate and the second base substrate corresponding to each other, together constitute a package unit. The semiconductor structure comprises a plurality of the package units arranged in an array in the first direction D1, and the third direction D3. The third direction D3 is parallel to the top surface of the first base substrate 91, and the third direction D3 intersects with the first direction D1. Subsequently, by dicing the semiconductor structure, the semiconductor structure is divided into a plurality of separate package units, and a single separate package unit is used as the package structure. The schematic diagrams of the package structure are shown in FIGS. 1-4.

In the package body 41 of the semiconductor structure in the present specific embodiment, a plurality of the first interconnection structures 12 located on the same side of the semiconductor chip 11 in the first direction D1 are arranged at intervals in the third direction D3, thereby avoiding the problem that the stress applied to the first base substrate 91 is too large due to the excessive length of the first interconnection structures, and reducing the probability of deformation such as warping during the manufacturing process of the semiconductor structure, and improving the performance and manufacturing yield of the semiconductor structure. A plurality of the first interconnection structures 12 located on the same side of the semiconductor chip 11 are arranged at intervals in the third direction D3 so that the functional devices 13 can be provided in the interval area between adjacent first interconnection structures 12, so as to increase the utilization rate of the space in the package body 41, and thus to enable more components to be integrated in the package, and to increase the integration degree of the semiconductor structure, which helps to realize high-density package integration and extend the functions of the package structure.

In some embodiments, the semiconductor structure further comprises a dicing lane area 90, extending from the second base substrate 92 to the first base substrate 91 in the second direction D2; a connection structure 51, located between adjacent package bodies 41 in the first direction D1 and the dicing lane area 90 passing through the connection structure 51 in the second direction D2, the connection structure 51 connecting the first interconnection structures 12 in two adjacent package bodies 41.

By way of example, in the two adjacent package bodies 41 in the first direction D1, the first interconnection structure 12 in one of the package bodies 41 on the side facing the other one of the package bodies 41, and the first interconnection structure 12 in the other one of the package bodies 41 on the side facing the one of the package bodies 41 are connected by one of the connection structures 51 (i.e., the first interconnection structures 12 within adjacent package bodies 41 are connected by the connection structure 51), thereby enabling simultaneous formation and simultaneous mounting of two adjacent first interconnection structures 12 to further simplify the manufacturing process of the semiconductor structure. The dicing lane area 90 passes through the connection structure 51 in the second direction D2, thereby enabling subsequent separation of adjacent first interconnection structures 12 at the same time when the semiconductor structure is cut in the dicing lane area 90.

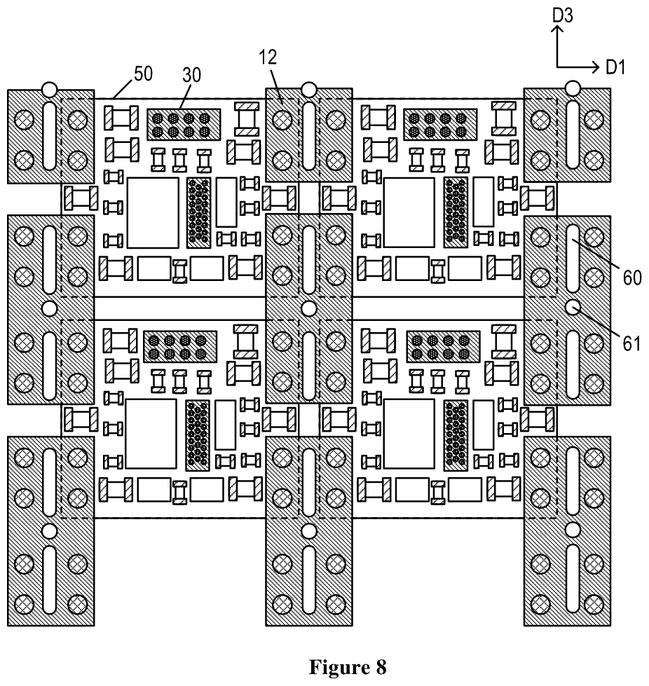

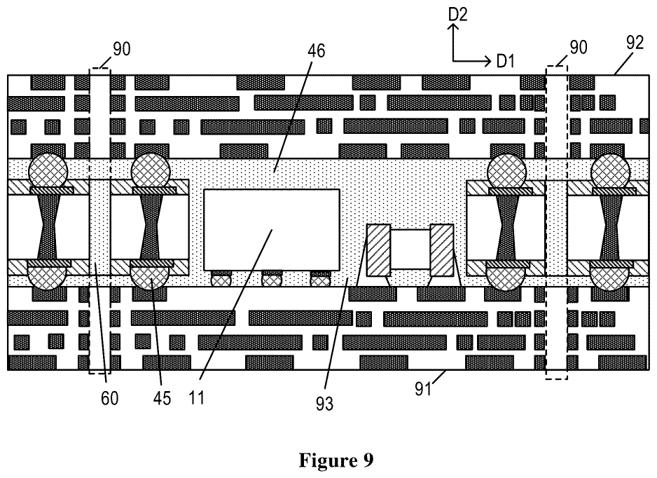

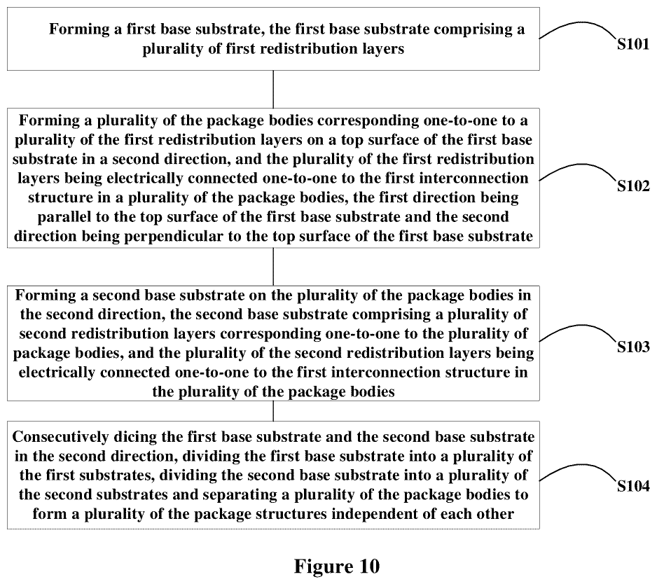

FIG. 6 is a second schematic top view of a semiconductor structure in some embodiments of the present disclosure, FIG. 7 is a third schematic top view of a semiconductor structure in some embodiments of the present disclosure, and FIG. 8 is a fourth schematic top view of a semiconductor structure in some embodiments of the present disclosure.

In some embodiments, as shown in FIGS. 6-9, the connection structure 51 comprises an isolation layer, the isolation layer connecting the first interconnection structures 12 in two adjacent package bodies 41; and grooves, located within the isolation layer. The grooves are located within the dicing lane area 90.

In some embodiments, a plurality of the first interconnection structures 12 within the package body 41 located on the same side of the semiconductor chip 11 are arranged at intervals in a third direction D3. The third direction D3 is parallel to the top surface of the first base substrate 91, and the first direction D1 intersects with the third direction D3.

The groove comprises a first groove 60, located between two adjacent first interconnection structures 12 in the package body 41, and a second groove 61, distributed on the outside of the first groove 60 in the third direction D3. The length of the first groove 60 in the third direction D3 is greater than the length of the second groove 61 in the third direction D3.

Specifically, as shown in FIGS. 6-9, in one example, the isolation layer in the connection structure 51 may comprise a first sub-isolation layer and a second sub-isolation layer covering the surface of the first sub-isolation layer, the first sub-isolation layer may be of the same material and synchronously formed with the first dielectric layer 42 in the first interconnection structure 12, and the second sub-isolation layer may be of the same material and synchronously formed with the first cover layer 121 in the first interconnection structure 12. The grooves in the isolation layer can act as stress relief channels to reduce the accumulation of stress within the package body 41, thereby further improving the performance of the semiconductor structure. In one example, the grooves run through the isolation layer in the second direction D2. By providing the first groove 60 and the second groove 61 with different dimensions, on the one hand, it is convenient to determine the position of the first interconnection structure 12 within the package body during the mounting process; on the other hand, it ensures the structural stability of the package body while sufficiently releasing the stress within the package body 41.

In some embodiments, the semiconductor structure further comprises molding compound 93, filled between the first base substrate 91 and the second base substrate 92, and molding the semiconductor chip 11, the functional device 13, and the first interconnection structure 12. The molding compound 93 fully fills the grooves.

Specifically, the molding compound 93 is consecutively filled within a plurality of the package units, and after subsequent dicing the semiconductor structures in the dicing area 90, the molding compound 93 located within a single package structure serves as the molding layer 46 of the package structure.

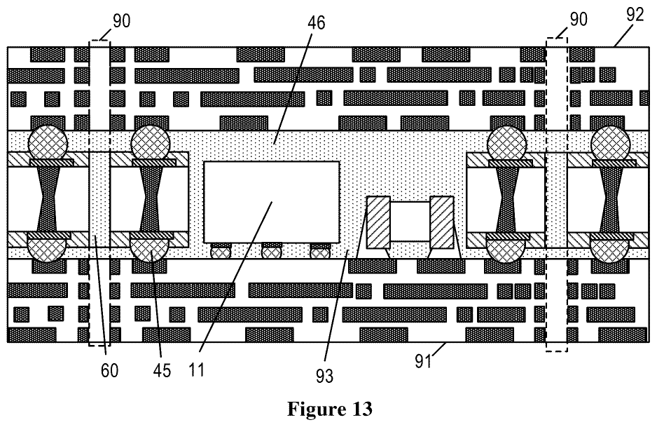

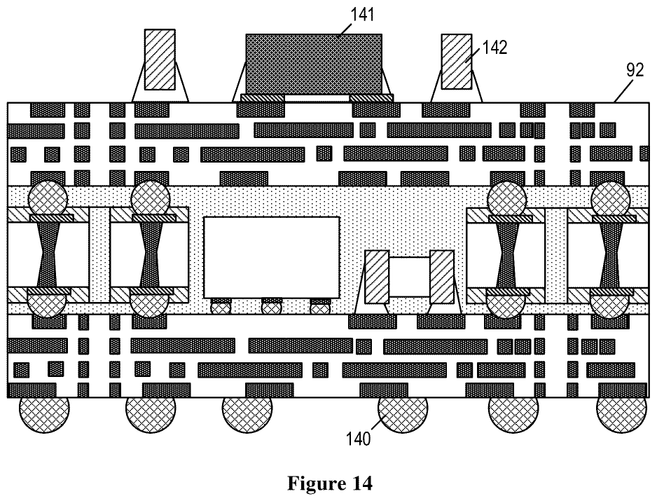

The present specific embodiment also provides a method for forming a package structure. FIG. 10 is a flowchart of a method for forming a package structure in some embodiments of the present disclosure, FIGS. 11-14 are schematic diagrams of the main process structures of the process for forming the package structure in specific embodiments of the present disclosure.

The schematic diagrams of the package structure formed in the present specific embodiment are shown in FIGS. 1-4. The method for forming the package structure comprises the following steps: forming a first substrate 10, a second substrate 40, and a package body 41 located between the first substrate 10 and the second substrate 40, the package 41 comprising a semiconductor chip 11, a functional device 13, and a plurality of first interconnection structures 12 located on at least one side of the semiconductor chip 11, the first interconnection structures 12 electrically connecting the first substrate 10 to the second substrate 40, the plurality of the first interconnection structures 12 located on the same side of the semiconductor chip 11 being arranged at intervals, the functional device 13 being located within an interval area between adjacent first interconnection structures 12.

In some embodiments, specific steps for forming the first substrate 10, the second substrate 40, and the package body 41 located between the first substrate 10 and the second substrate 40 comprise the following.

At step S101, a first base substrate 91 is formed, the first base substrate 91 comprising a plurality of first redistribution layers.

At step S102, a plurality of the package bodies 41 corresponding one-to-one to a plurality of the first redistribution layers are formed on the top surface of the first base substrate 91 in a second direction D2. The plurality of the first redistribution layers are electrically connected one-to-one to the first interconnection structure 12 in the plurality of the package bodies 41. The first direction D1 is parallel to the top surface of the first base substrate 91, and the second direction D2 is perpendicular to the top surface of the first base substrate 91, as shown in FIG .11.

At step S103, a second base substrate 92 is formed on the plurality of the package bodies 41 in the second direction D2, the second base substrate 92 comprising a plurality of second redistribution layers corresponding one-to-one to a plurality of package bodies 41, and the plurality of the second redistribution layers electrically connected one-to-one to the first interconnection structure 12 in the plurality of the package bodies 41, as shown in FIG. 12.

At step S104, the first base substrate 91 and the second base substrate 92 are consecutively diced in the second direction D2. The first base substrate 91 is divided into a plurality of the first substrate 10, the second base substrate 92 is divided into a plurality of the second substrate 40, and a plurality of the package bodies 41 are separated to form a plurality of the package structures independent of each other, as shown in FIGS. 1-4. The schematic diagrams of the semiconductor structure before consecutively dicing the first base substrate 91 and the second base substrate 92 in the second direction D2 are shown in FIGS. 5-9.

In some embodiments, the specific steps for forming a plurality of the package bodies 41 corresponding one-to-one to a plurality of the first redistribution layers on a top surface of the first base substrate 91 in the second direction D2 comprise defining a mounting area in the first base substrate 91 and a first dicing lane area 110 located between adjacent mounting areas, the first redistribution layer being located within the mounting area; mounting the semiconductor chip 11, the functional device 13 and the first interconnection structure 12 on the mounting area, and connecting the first interconnection structure 12 on the adjacent mounting area through a connection structure 51 located on the first dicing lane area 110.

In some embodiments, the specific steps of prior to mounting the semiconductor chip 11, the functional device 13, and the first interconnection structure 12 on the mounting area, and connecting the first interconnection structure 12 on the adjacent mounting area through a connection structure located on the first dicing lane area 110 comprise: forming an initial connection structure comprising a plurality of the first interconnection structures 12 and located between adjacent first interconnection structures and connecting connection structures 51 of the plurality of the first interconnection structures 12; mounting the semiconductor chip 11 in the mounting area and mounting the initial connection structure and the functional device 13 on the first base substrate 91 such that the first interconnection structure 12 of the initial connection structure is located within the mounting area and the connection structure 51 is located within the first dicing lane area 110.

In some embodiments, the steps of mounting the semiconductor chip 11, the functional device 13, and the first interconnection structure 12 on the mounting area comprise mounting the semiconductor chip 11 and the second interconnection structure 20 in the middle of the mounting area, mounting the first interconnection structure 12 and the functional device 13 at the edge of the mounting area, the second interconnection structure 20 being electrically connected to the first redistribution layer.

By way of example, after forming the first base substrate 91, the semiconductor chip 11, the functional device 13, the initial connection structure, the second interconnection structure 20, and the third interconnection structure 30 are mounted above each mounting area such that the connection structure 51 in the initial connection structure is located on the first dicing lane area 110 between two adjacent mounting areas. The semiconductor chip 11, the second interconnection structure 20, and the third interconnection structure 30 are located in the middle of the mounting area, the first interconnection structure 12 and the functional device 13 are located at the edge of the mounting area in the first direction D1, and the semiconductor chip 11, the first interconnection structure 12, the second interconnection structure 20 and the third interconnection structure 30 are all electrically connected to the first redistribution layer. Thereafter, a second base substrate 92 is formed on a plurality of the package bodies 41 in the second direction D2, the second base substrate 92 comprising a plurality of the second redistribution layers and a second dicing lane area 120 located between adjacent second redistribution layers, the second dicing lane area 120 and the first dicing lane area 110 being aligned in the second direction D2 to form a dicing lane area 90 comprising the first dicing lane area 110 and the second dicing lane area 120, as shown in FIG. 12.

In some embodiments, the connection structure 51 comprises an isolation layer connecting adjacent first interconnection structure 12 and a groove located within the isolation layer; and prior to consecutively dicing the first base substrate 91 and the second base substrate 92 in the second direction D2, it further comprises the following steps: filling between the first base substrate 91 and the second base substrate 92 with a molding compound 93 which molds the semiconductor chip 11, the functional device 13, and the first interconnection structure 12, and the molding compound 93 fully fills the grooves.

In some embodiments, the second base substrate 92 comprises a second dicing lane area 120 corresponding to the first dicing lane area 110; the specific steps of consecutively dicing the first base substrate 91 and the second substrate 92 in the second direction D2 comprise consecutively dicing the second dicing lane area 120, the initial connection structure and the first dicing lane area 110 in the second direction D2, dividing the first base substrate 91 into a plurality of the first substrates 10, dividing the second base substrate 92 into a plurality of the second substrates 40, and dividing the initial connection structure into a plurality of independent first interconnection structures 12.

By way of example, after filling the molding compound 93 between the first base substrate 91 and the second base substrate 92, device structures (e.g., functional chips 141 and discrete devices 142) may also be mounted on the side of the second base substrate 92 facing away from the first substrate 91 in the second direction D2, and a solder ball 140 may be formed on the side of the first base substrate 91 facing away from the second base substrate 92. Next, the second dicing lane area 120, the initial attachment structure, and the first dicing lane area 110 are consecutively diced in the second direction D2, to form a plurality of the package structures independent of each other, each of the package structures comprising the first substrate 10 and the second substrate 40, and one of the package bodies 41 located between the first substrate 10 and the second substrate 40.

In the package structure and the method for forming the same, as well as the semiconductor structure provided by the present disclosure, by providing a plurality of first interconnection structures on at least one side of a semiconductor chip within a package body, and arranging a plurality of the first interconnection structures located on the same side of the semiconductor chip at intervals, the deformation such as warping of the package structure during manufacturing caused by too long length of the first interconnection structures is avoided, and the manufacturing yield of the package structure is improved and the performance of the package structure is ensured. By providing functional devices in the interval area between the adjacent first interconnection structures on one side of the semiconductor chip, the utilization rate of space in the package is improved, thereby enabling more components to be integrated within the package, and the integration degree of the package structure is improved, which helps to realize high-density package integration and extend the functions of the package structure.

The foregoing is only a preferred embodiment of the present disclosure, and it should be noted that for a person of ordinary skilled in the art, a number of improvements and refinements may be made without departing from the principles of the present disclosure, and these improvements and refinements should also be deemed to fall within the protection scope of the present disclosure.

What is claimed is:

1. A package structure, comprising:
a first substrate;
a second substrate, located above the first substrate; and
a package body, located between the first substrate and the second substrate, the package body comprising a semiconductor chip, a functional device, and a plurality of first interconnection structures located on at least one side of the semiconductor chip, the first interconnection structures electrically connecting the first substrate to the second substrate, the plurality of the first interconnection structures located on a same side of the semiconductor chip are arranged at intervals, and the functional device is located within an interval area between the adjacent first interconnection structures.

2. The package structure according to claim 1, wherein two first interconnection structures are arranged at intervals on the same side of the semiconductor chip, and the two first interconnection structures are symmetrically distributed with respect to the functional device.

3. The package structure according to claim 1, wherein
the plurality of the first interconnection structures are distributed in a first direction on opposite sides of the semiconductor chip; and
for the first interconnection structures distributed in the first direction on opposite sides of the semiconductor chip, a spacing distance between the adjacent first interconnection structures located on one side of the semiconductor chip is the same as or different from the spacing distance between the adjacent first interconnection structures located on another side of the semiconductor chip.

4. The package structure according to claim 1, wherein
the package body further comprises a molding layer filled between the first substrate and the second substrate;
the molding layer molds the semiconductor chip, the functional device, and the first interconnection structures; and
the molding layer fully fills the interval area between the adjacent first interconnection structures.

5. The package structure according to claim 1, wherein
the first interconnection structures further comprise a plurality of first bottom pins electrically connected to the first substrate, and there is a first spacing distance between the adjacent first bottom pins; and
in the plurality of the first interconnection structures, there is at least one of the first interconnection structures in which the first spacing distance is different from the first spacing distance in another first interconnection structure.

6. The package structure according to claim 5, wherein
the semiconductor chip is located in a middle of the package body, and the first interconnection structure is located at an edge of the package body; and
the package body further comprises a second interconnection structure, located in a middle of the package body, the second interconnection structure electrically connecting the first substrate to the second substrate, the second interconnection structure comprising a plurality of second bottom pins electrically connecting the first substrate, and
there is a second spacing distance between the adjacent second bottom pins, the second spacing distance being less than the first spacing distance.

7. A semiconductor structure, comprising:
a first base substrate, the first base substrate comprising a plurality of first redistribution layers;
a second base substrate, located on a top surface of the first base substrate in a second direction, wherein the second base substrate comprises a plurality of second redistribution layers, a first direction is parallel to the top surface of the first base substrate, and the second direction is perpendicular to the top surface of the first base substrate; and
a plurality of package bodies, located between the first base substrate and the second base substrate, each of the package bodies comprising a semiconductor chip, a functional device, and a plurality of first interconnection structures located on at least one side of the semiconductor chip, the first interconnection structures electrically connecting the first base substrate to the second base substrate, the plurality of the first interconnection structures located on a same side of the semiconductor chip are arranged at intervals, and the functional device located within an interval area between the adjacent first interconnection structures.

8. The semiconductor structure according to claim 7, further comprising:
a dicing lane area, extending from the second base substrate to the first base substrate in the second direction; and
a connection structure, located between the adjacent package bodies in the first direction, and the dicing lane area passing through the connection structure in the second direction, the connection structure connecting the first interconnection structures in the two adjacent package bodies.

9. The semiconductor structure according to claim 8, wherein the connection structure comprises:
an isolation layer, the isolation layer connecting the first interconnection structures in the two adjacent package bodies; and
grooves, located within the isolation layer and the grooves are located within the dicing lane area.

10. The semiconductor structure according to claim 9, wherein
the plurality of the first interconnection structures located on the same side of the semiconductor chip within the package are arranged at intervals in a third direction, the third direction being parallel to the top surface of the first base substrate and the first direction intersecting with the third direction; and
the grooves comprise:
a first groove, located between the first interconnection structures in the two adjacent package bodies; and
a second groove, located on an outside of the first groove in a third direction, and a length of the first groove in the third direction is greater than the length of the second groove in the third direction.

11. The semiconductor structure according to claim 9, further comprising:
a molding compound, filled between the first base substrate and the second base substrate and molding the semiconductor chip, the functional device, and the first interconnection structure, the molding compound fully filling the grooves.

12. The semiconductor structure according to claim 7, wherein
each of the package bodies further comprises a molding layer filled between the first base substrate and the second base substrate;
the molding layer molds the semiconductor chip, the functional device, and the first interconnection structures; and
the molding layer fully fills the interval area between the adjacent first interconnection structures.

13. The semiconductor structure according to claim 7, wherein
the first interconnection structures further comprise a plurality of first bottom pins electrically connected to the first base substrate, and there is a first spacing distance between the adjacent first bottom pins; and
in the plurality of the first interconnection structures, there is at least one of the first interconnection structures in which the first spacing distance is different from the first spacing distance in another first interconnection structure.

14. A method for forming a package structure, comprising:
forming a first substrate, a second substrate, and a package body located between the first substrate and the second substrate, the package body comprising a semiconductor chip, a functional device, and a plurality of first interconnection structures located on at least one side of the semiconductor chip, the first interconnection structures electrically connecting the first substrate to the second substrate, the plurality of the first interconnection structures located on a same side of the semiconductor chip are arranged at intervals, the functional device is located within an interval area between the adjacent first interconnection structures.

15. The method for forming a package structure according to claim 14, wherein forming a first substrate, a second substrate, and a package body located between the first substrate and the second substrate comprises:
forming a first base substrate, the first base substrate comprising a plurality of first redistribution layers;
forming a plurality of the package bodies corresponding one-to-one to a plurality of the first redistribution layers on a top surface of the first base substrate in a second direction, and the plurality of the first redistribution layers being electrically connected one-to-one to the first interconnection structures in a plurality of the package bodies, a first direction being parallel to the top surface of the first base substrate and the second direction being perpendicular to the top surface of the first base substrate;
forming a second base substrate on the plurality of the package bodies in the second direction, the second base substrate comprising a plurality of second redistribution layers corresponding one-to-one to the plurality of package bodies, and the plurality of the second redistribution layers being electrically connected one-to-one to the first interconnection structures in the plurality of the package bodies; and
consecutively dicing the first base substrate and the second base substrate in the second direction, dividing the first base substrate into a plurality of the first substrates, dividing the second base substrate into a plurality of the second substrates, and separating a plurality of the package bodies to form a plurality of the package structures independent of each other.

16. The method for forming a package structure according to claim 15, wherein forming a plurality of the package bodies corresponding one-to-one to a plurality of the first redistribution layers on a top surface of the first base substrate in a second direction comprises:
defining in the first base substrate, mounting areas, and a first dicing lane area located between the adjacent mounting areas, the first redistribution layer being located within the mounting areas; and
mounting the semiconductor chip, the functional device and the first interconnection structure on the mounting area and connecting the first interconnection structures on the adjacent mounting areas through a connection structure located on the first dicing lane area.

17. The method for forming a package structure according to claim 16, wherein prior to mounting the semiconductor chip, the functional device, and the first interconnection structure on the mounting area, and connecting the first interconnection structures on the adjacent mounting areas through a connection structure located on the first dicing lane area comprises:
forming an initial connection structure comprising the plurality of the first interconnection structures and located between the adjacent first interconnection structures and connecting connection structures of the plurality of the first interconnection structures; and
mounting the semiconductor chip and the functional device in the mounting area and mounting the initial connection structure on the first base substrate such that the first interconnection structures of the initial connection structure are located within the mounting area, and the connection structure is located within the first dicing lane area.

18. The method for forming a package structure according to claim 17, wherein mounting the semiconductor chip, the functional device, and the first interconnection structure on the mounting area comprise:
mounting the semiconductor chip and a second interconnection structure in a middle of the mounting area, mounting the first interconnection structure and the functional device at an edge of the mounting area, the second interconnection structure being electrically connected to the first redistribution layer.

19. The method for forming a package structure according to claim 17, wherein
the connection structure comprises an isolation layer connecting the adjacent first interconnection structures and a groove located within the isolation layer; and
prior to consecutively dicing the first base substrate and the second base substrate in the second direction, the method further comprises:
filling between the first base substrate and the second base substrate with a molding compound which molds the semiconductor chip, the functional device, and the first interconnection structure, the molding compound fully filling the groove.

20. The method for forming a package structure according to claim 17, wherein
the second base substrate comprises a second dicing lane area corresponding to the first dicing lane area; and
consecutively dicing the first base substrate and the second base substrate in the second direction comprise:
consecutively dicing the second dicing lane area, the initial connection structure, and the first dicing lane area in the second direction, dividing the first base substrate into a plurality of the first substrates, dividing the second base substrate into a plurality of the second substrates, and dividing the initial connection structure into a plurality of independent first interconnection structures.
